(19) United States
(12) Patent Application Publication
(10) Pub. No.: US 2022/0310854 A1
(43) Pub. Date: Sep. 29, 2022

(54) SOLAR CELL CONTACT ARRANGEMENT

(71) Applicant: AZUR SPACE Solar Power GmbH, Heilbronn (DE)

(72) Inventors: Wolfgang KOESTLER, Heilbronn (DE); Tim KUBERA, Leingarten (DE)

(73) Assignee: AZUR SPACE Solar Power GmbH, Heilbronn (DE)

(21) Appl. No.: 17/685,104

(22) Filed: Mar. 2, 2022

(30) Foreign Application Priority Data
Mar. 2, 2021 (DE) 10 2021 001 117.1
May 26, 2021 (DE) 10 2021 002 720.5
Sep. 20, 2021 (DE) 10 2021 004 707.9

(51) Int. Cl. H01L 31/02

(52) U.S. Cl. CPC H01L 31/02021

(57) ABSTRACT

A solar cell contact arrangement, having a semiconductor body with a top and a bottom, wherein the semiconductor body has multiple solar cell stacks and includes a support substrate on the bottom, and each solar cell stack has at least two III-V subcells arranged on the support substrate and at least one through-contact extending from the top to the bottom of the semiconductor body with a continuous side wall, wherein the through-contact has a first edge region on the top and a second edge region on the bottom, and the first edge region has a first section and a second, metallic section, and the second edge region has a first section and a second section, wherein the respective second sections completely enclose the respective first sections, and an insulating layer.

This nonprovisional application claims priority under 35 U.S.C. § 119(a) to German Patent Application No. 10 2021 001 117.1, which was filed in Germany on Mar. 2, 2021, and to German Patent Application No. 10 2021 002 720.5, which was filed in Germany on May 26, 2021, and to German Patent Application No. 10 2021 004 707.9, which was filed in Germany on Sep. 20, 2021 and which are all herein incorporated by reference.

### BACKGROUND OF THE INVENTION

### Field of the Invention

The present invention relates to a solar cell contact arrangement.

### Description of the Background Art

In order to reduce the shadowing of the front side of a solar cell, it is possible to arrange both the positive and the negative external contact areas on the rear side. In the case of so-called metal wrap through (MWT) solar cells, contact is made with the front side of the solar cell from the rear side by means of a through-contact opening, for example.

Various methods are known for producing a hole or a through-contact opening through a solar cell. The metallization extending through the through-opening is insulated from the layers of the solar cell stack by means of an insulating layer.

For example, a solar cell contact arrangement is known from U.S. Pat. No. 9,680,035 B1 with a solar cell stack comprising multiple III-V subcells on a GaAs substrate with a front side contacted through the rear side. In this design, a hole extending from the top of the solar cell through the subcells into an as-yet unthinned substrate layer is created by means of a wet chemical etching process. Passivation and metallization of the front side and of the hole is performed before the thinning of the substrate layer.

### SUMMARY OF THE INVENTION

It is therefore an object of the present invention to advance the state of the art.

According to an exemplary embodiment of the invention, a solar cell contact arrangement is provided.

The solar cell contact arrangement includes a semiconductor body with a top and a bottom.

The semiconductor body includes at least one solar cell stack on the top, and a support substrate on the bottom.

Each solar cell stack includes at least two III-V subcells arranged on the support substrate, and at least one through-contact extending from the top to the bottom of the semiconductor body.

The through-contact has a continuous side wall with a first edge region formed on the top and a second edge region formed on the bottom.

The first edge region has a first section and a second, metallic section, and the second edge region has a first section and a second section.

In addition, an insulating layer is formed on the first section in the case of the first edge region, on the side wall, and on the first section and the second section in the case of the second edge region.

The insulating layer has a thickness between 5 μm and 200 μm.

Furthermore, an electrically conductive layer is formed on the first section and the second section in the case of the first edge region, at the side wall, and on the first section in the case of the second edge region, wherein the electrically conductive layer is at least partially arranged on the insulating layer.

The electrically conductive layer is formed as a heterogeneous layer with gas inclusions, and has a thickness between 5 μm and 200 μm.

It should be noted that the gas inclusions make up at least one volume percent and at most forty volume percent of the total volume of the electrically conductive layer, or the electrically conductive layer contains gas inclusions between two and ten volume percent.

On the top, the electrically conductive layer in the case of the first edge region is formed over the first section and at least partially beyond it in order to make contact with a front metal structure.

On the bottom, the electrically conductive layer in the case of the second edge region is formed within the first section, and not on the second section. In other words, the electrically conductive layer lies completely on the insulating layer in the case of the second edge region.

The electrically conductive layer has organic constituents. In an improvement, the electric layer undergoes an annealing process of at least 200° C. and a duration of at least 5 min.

The semiconductor body can be implemented as a semiconductor wafer. In an improvement, the semiconductor body comprises multiple solar cell stacks. Preferably, exactly two solar cell stacks are formed on the semiconductor wafer.

The electrically conductive layer can be formed solely on the first section in the case of the second edge region.

The electrically conductive layer at least partially or completely covers the first section in the case of the second edge region.

The insulating layer can be formed solely on the first section in the case of the first edge region.

It is a matter of course that the electrically conductive layer is arranged on the insulating layer if the insulating layer is formed.

Preferably, there is an integral connection between the insulating layer and the electrical layer.

It should be noted that the insulating layer completely covers the side wall, which is to say the area of the through-contact perpendicular to the surface.

The first section in the case of the first edge region and the first section and the second section in the case of the second edge region can each be covered at least partially or completely by the insulating layer.

It should be noted that the term “insulating layer” can also be understood to mean, for example, a dielectric layer system that includes the insulating layer. In addition, the term “edge region” can refer to a region on the top and on the bottom arranged directly at the through-opening in each case.

It should be noted that irradiation of light takes place on the top of the semiconductor body. In order to shadow as little of the top as possible, the top is electrically connected by means of a metallic finger structure.

The band gap of the III-V subcells can decrease from subcell to subcell from the top in the direction of the support substrate.

In general, the subcells of the relevant solar cell stack can have an n on p arrangement. It is a matter of course that one tunnel diode is formed between every two subcells in order to connect the individual subcells in series from an electrical perspective. In particular, the topmost subcell includes a compound of InGaP and has a band gap greater than 1.7 eV.

A generally finger-shaped top metallization can be arranged on the top in order to electrically connect the front side. The top metallization is also referred to hereinafter as a metal structure.

It is a matter of course that, for each solar cell stack, the top is electrically connected from the rear side by means of one or more through-openings.

For example, the semiconductor body, which is implemented, for example, as a semiconductor wafer and preferably has a diameter of 100 mm or 150 mm, is thinned to the desired final thickness prior to the formation of the through-opening. For this purpose, support substrate is removed on the rear side.

In addition, it should be noted that the semiconductor body implemented in an improvement as a semiconductor wafer has multiple solar cell stacks that have not been diced, wherein the support substrate forms the bottom of the semiconductor body. It is a matter of course that the solar cell stack also has 3 or 4 or 5 or a maximum of 6 subcells.

In an improvement, precisely one of the multiple subcells in each case can be implemented as a Ge subcell in this design.

An advantage of the solar cell contact arrangement is that a front side of the solar cell stack formed on the top is connected from the bottom by means of the through-contact. In other words, the solar cell stack is electrically connected solely from the rear side. The formation of metal areas, which is to say pads, on the front side is unnecessary. The receiving area on the front side becomes larger, and the efficiency of the arrangement increases.

The formation of the through-connection, which is to say the formation of an electrical connection to the front side from the rear side, simplifies the electrical connection of the solar cell stack. Another advantage is that both contacts, which is to say the n-contact and the p-contact, for example, can be connected at the rear side with a single soldering process step. The yield and the reliability can be increased by this means.

It is noted that the formation of the solar cell contact arrangement preferably can take place with one or more applications of a printing process. Preferably, the top and the rear side are coated with the insulating layer by means of a first printing process, and the front side and the rear side are coated with the electrical layer by means of a second printing process.

In this context, the first printing process and the second printing process each can comprise one or more process steps.

For example, only one side of the semiconductor body and the through-opening can be printed in a first process step in each case, and subsequently the other side of the semiconductor body and the through-opening, or with the exception of the through-opening, are printed in a second process step in each case.

Alternatively, the first printing process and/or the second printing process each can comprises only a single process step in which both sides of the semiconductor body are printed in each case.

In an improvement, one side of the semiconductor body can be printed by means of a material passed through the through-opening in the case of the first process step and/or the second process step when the respective single printing step is carried out.

Because the relevant layers can be applied in a structured fashion by means of the printing process, photolithographic process steps are unnecessary. In other words, both the insulating layer and the electrically conductive layer can be reliably and economically applied in a structured fashion.

An advantage of the printing process additionally resides in that the abovementioned layers readily can be applied reliably even when there are large differences in the topography. Expensive and complicated masking steps are avoided. It is also possible to form reliable protection of the insulating layer in the region of the through-opening. In particular, the time and technical effort as well as the material consumption are small in comparison with the prior art by means of resist masks. Reliability and yield can be increased by this means.

The through-opening and the regions adjoining the through-opening on the top and on the bottom can be covered exclusively by means of the printing process. Highly efficient and reliable multi-junction solar cells, the front side of which is electrically connected to the rear side, can be produced in a simple and economical manner with the process.

The electrically conductive layer can be formed on the bottom of the support substrate in a first contact region. The top of the semiconductor wafer, which is to say the front side of the solar cell stack, can be electrically connected on the rear side by this means.

A second contact region can be formed on the bottom of the support substrate. The bottom of the electrically conductive support substrate can be electrically connected by means of the second contact region. Preferably, the first contact region is formed as an n-contact and the second contact region as a p-contact. It is a matter of course that the two contact regions on the bottom are spaced apart from one another in order to ensure electrical insulation.

Both contact regions can be planar and can each encompass a size of at least 1.0 mm². In an embodiment, the two contact regions have at least partly the same height. In other words, the surfaces of the two contact regions are an equal distance from the bottom of the support substrate. One advantage is that the two contact regions can be connected simultaneously to an underlayer by means of a so-called reflow soldering step, for example.

The first contact region, which is to say the electrically conductive layer, can have an integral connection with the insulating layer located below it. In particular, the electrical layer has a full integral connection with the insulating layer in the first contact region.

The diameter of the through-opening in the support substrate can be constant to a first approximation or exactly constant or follows a conical course from the top in the direction of the bottom.

After the formation of the conductive layer, the through-opening can be partially or completely closed or the through-opening still has a through hole.

The first edge region at the top can have a different, in particular smaller, diameter than the second edge region at the bottom.

The first edge region and the second edge region can each be implemented as an edge region completely surrounding the through-opening. Preferably, the respective edge region parallel to the semiconductor body has a diameter of at least 10 μm and at most 3.0 mm. Alternatively, the respective edge region parallel to the semiconductor body has a diameter of at least 100 μm and at most 1.0 mm.

The through-opening of the semiconductor body can have an overall height of at most 500 μm and at least 30 μm, or at most 200 μm and at least 50 μm.

The through-opening can have an oval perimeter in cross-section, in particular a round perimeter. Preferably, the through-opening has a diameter between 25 μm and 1 mm prior to the application of the first printing process, which is to say without a formation of the insulating layer. Alternatively, the diameter of the through-opening is in a range from 50 μm to 300 μm.

The support substrate can be designed to be electrically conductive. Preferably, the support substrate includes germanium or GaAs or silicon or is composed of one of the aforementioned materials. Alternatively, the support substrate includes a metal foil or includes an electrically conductive plastic.

The through-opening can be oval in design. In the present case, the term “oval” also can include round, in particular circular, ovoid, and elliptical shapes.

The through-opening can be implemented as a rectangular or square shape with rounded corners.

A first bake step can be carried out after the first printing process and before execution of the second printing process. In another improvement, a second bake step is carried out after the second printing process. The insulating layer and the conductive layer are each conditioned by means of the bake steps. Preferably the bake steps are carried out in a temperature range between 100° C. and 450° C.

A paste can be used to form the insulating layer. Preferably the paste includes organic constituents.

A paste containing metal particles can be used to form the conductive layer.

The first printing process and/or the second printing process can be carried out solely from the front side or solely from the rear side. Alternatively, the first printing process and/or the second printing process is carried out both from the front side and from the rear side.

The through-opening still can have a through hole after the formation of the insulating layer. Alternatively, the through-opening is opened in a central region by means of a laser.

The conductive layer can be composed of the same material on the first edge region and in the through-opening and on the second edge region. In an alternative embodiment, different compositions are used to form the conductive layer on the top and on the bottom.

If the through-opening is completely closed by means of the conductive layer, the conductive layer can project beyond the top and/or at the bottom. Alternatively, the conductive layer on the bottom, with the conductive layer in the center of the through-opening, forms an area that is flat to a first approximation on the insulating layer.

The printing process can be carried out by means of an inkjet process or a screen printing process or by means of a dispensing process. The printing process may also be carried out by means of a stencil printing process. In another improvement, at least two of the different printing processes are combined.

The diameter of the through-opening prior to the application of the printing process can be constant to a first approximation or exactly constant in the support substrate from the direction of the top toward the bottom.

The diameter of the through-opening can also become smaller from the top in the direction toward the bottom, wherein the taper preferably is designed to be step-like. In an improvement, the through-opening has an hourglass-shaped appearance in a cross-section. In this case, the cross-section tapers to approximately half the total thickness.

The taper in the through-opening can comprise exactly one fully surrounding step or exactly two fully surrounding steps.

Preferably, the semiconductor body or the support substrate can have a size of 100 mm or 150 mm or greater.

If the support substrate includes or is composed of germanium, the Ge support substrate forms the bottom of the semiconductor body. Preferably, a first subcell can be implemented as a Ge subcell in the Ge support substrate on the side facing away from the bottom, wherein the Ge subcell has the smallest band gap of the subcells of the solar cell stack.

When Ge is used as the support substrate, a first step is formed at the interface between Ge subcell and the III-V subcell resting thereon. A second step is preferably formed between the Ge subcell and the support substrate.

Preferably, the through-opening can also taper within the Ge substrate. The stepped or conical implementation of the through-opening has the advantage that the layers on the side surfaces are can be made sufficiently thick within the framework of a metallization, in particular in the case of a preferably conformal deposition of the insulating layer and/or additional layers to be applied.

In an improvement, an additional step can be formed on the top of the semiconductor body at the interface between metal structure and the top of the topmost III-V subcell.

The solar cell stack can have a Ge subcell. In consequence, the solar cell stack comprises at least 3 subcells.

A part of the insulating layer on the top can be formed on a metal area. It is possible to ensure by this means that the metal structure, which is to say the front side of the solar cell stack, is connected on the top.

In other words, because the conductive layer reaches over the insulating layer on the top and forms an integral connection with a part of the metal structure, but only covers the part of the second edge region immediately adjacent to the through-opening on the bottom, a contact region for an electrical connection to the metal structure MV is formed on the bottom by this means.

In an improvement, the respective second sections completely enclose the respective first sections.

The proportion of the organic constituents in the electrical layer can be between 0.1 and 5 volume percent or between 0.2 and 2 volume percent. It is a matter of course that the electrical layer is applied to the surface by means of the printing process using an organometallic paste.

In another improvement, the thickness of the part of the electrical layer directly at a corner of the first edge region to the through-opening can be at least half the thickness of the part of the electrical layer resting on the second edge region.

In an improvement, the through-opening can be completely filled after the formation of the electrical layer.

The insulating layer can include organic components. Preferably, the proportion of organic components is in a range between 0.1% to 5% volume percent.

In an improvement, the insulating layer can have a thickness between 5 μm and 200 μm or between 5 μm and 250 μm and/or the electrically conductive layer has a thickness between 5 μm and 500 μm. In another improvement, the thickness of the insulating layer is between 10 μm and 100 μm and/or the thickness of the electrically conductive layer is between 10 μm and 200 μm.

The electrically conductive layer can have a metal volume fraction of less than 99% and more than 50%.

The electrical conductivity can be between 30% and 90% of the metallic conductivity of a homogeneously formed metal layer with a material composition that is identical to a first approximation.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a cross-sectional view of a metallized through-opening in one embodiment,

FIG. 2 is a cross-sectional view of a metallized through-opening in another embodiment,

FIG. 3 is a cross-sectional view of a metallized through-opening in a different embodiment,

FIG. 4a is a top view of the top of the metallized through-opening corresponding to the embodiment shown in connection with the illustration in FIG. 3,

FIG. 4b is a top view of the bottom of the metallized through-opening corresponding to the embodiment shown in connection with the illustration in FIG. 3,

FIG. 5 is a cross-sectional view of a metallized through-opening with a first contact region and a second contact region,

FIG. 6 is a top view of a semiconductor body with two solar cell stacks.

### DETAILED DESCRIPTION

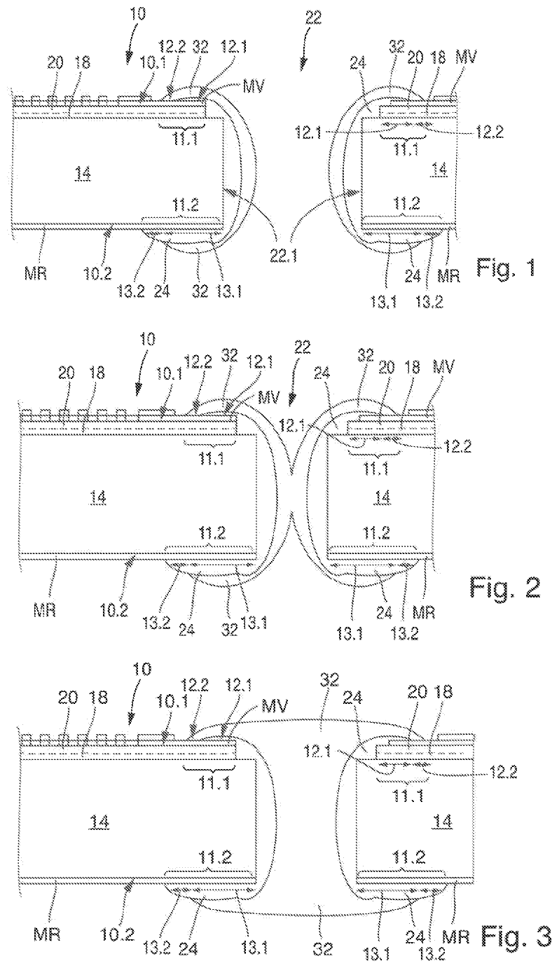

The illustration in FIG. 1 shows a cross-sectional view of a metallized through-opening 22 of a semiconductor body 10.

A semiconductor body 10 with a top 10.1, a bottom 10.2, and a through-opening 22 extending from the top 10.1 to the bottom 10.2 with a continuous side wall 22.1 is provided.

The semiconductor body 10 includes multiple solar cell stacks 12 that have not yet been diced, each with a layer sequence composed of a support substrate 14 forming the bottom 10.2, a first III-V subcell 18, and a second III-V subcell 20 forming the top 10.1; only one solar cell stack 12 is shown in the present illustration.

A metal structure MV is formed on the top 10.1. The metal structure MV is implemented almost exclusively as a finger-shaped structure and has, in particular in the first edge region 11.1 of the through-opening 22, a continuous metal area formed completely around the through-opening 22.

Formed on the bottom 10.2 is a full-area rear-side metallization MR in order to connect the conductive support substrate 14. It is a matter of course that the respective solar cell stack 12 is electrically connected using the two metallizations MV and MR.

The through-opening 22 has a first edge region 11.1 on the top 10.1 and a second edge region 11.2 on the bottom 10.2. The first edge region 11.1 is formed directly on the metal structure MV and the second edge region 11.2 is formed directly on the rear-side metallization MR.

The first edge region 11.1 has a first section 12.1 and a second, metallic section 12.2. The second edge region 11.2 has a first section 13.1 and a second section 13.2. Hereinafter, the first section 12.1 of the first edge region 11.1 and the second section 12.2 of the first edge region 11.1 are also referred to as the first part or as the second part of the first edge region.

Accordingly, the first section 13.1 and the second section 13.2 of the second edge region 11.2 are also referred to as the first part or as the second part of the second edge region 11.2.

A part of the first edge region 11.1 formed directly around the through-opening 22, the entire second edge region 11.2, as well as the side wall 22.1 of the through-opening 22 are coated with an insulating layer 24, wherein the insulating layer 24 is formed with a first printing process. It is a matter of course that the side wall 22.1 in the through-opening 22 is completely covered by the insulating layer 24.

By means of a second printing process, a conductive layer 32 is applied to the entire area of the first edge region 11.1 and completely to the entire area of the side wall 22.1 and to a part of the second edge region 11.2 directly adjacent to the through-opening 22. In the present case, the through-opening 22 is still open, even after the conductive layer 32 has been formed.

Because the conductive layer 32 reaches over the insulating layer 24 on the top 10.1 and forms an integral connection with a part of the metal structure MV, but only covers the part of the second edge region 11.2 immediately adjacent to the through-opening 22 on the bottom 10.2, a contact region for a connection to the metal structure MV is formed on the bottom 10.2 by this means.

In the illustration in FIG. 2, another embodiment is shown. Only the differences from the illustration in FIG. 1 are explained below.

In the embodiment shown, the conductive layer 32 meets in the middle of the substrate 14 and forms a profile in the shape of an hourglass.

In the illustration in FIG. 3, a different embodiment is shown. Only the differences from the illustration in FIG. 1 are explained below.

In the embodiment shown, the through-opening 22 is completely filled by the conductive layer 32 and forms a bump projecting from the top 10.1 and one projecting from the bottom 10.2.

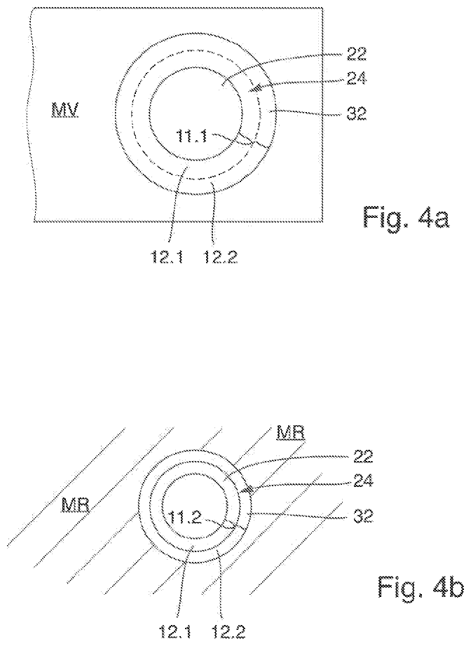

In the illustration in FIG. 4a, a top view of the top of the metallized through-opening 22 corresponding to the embodiment shown in connection with the illustration in FIG. 3 is illustrated.

The first edge region 11.1, as part of the metal structure MV, completely encloses the through-opening 22. The part of the first edge region 11.1 covered by the insulating layer 24 is drawn in dashed lines. It becomes apparent that the conductive layer 32 completely covers the insulating layer 24 on the top 10.1.

In the illustration in FIG. 4b, a top view of the bottom of the metallized through-opening 22 corresponding to the embodiment shown in connection with the illustration in FIG. 3 is illustrated.

The second edge region 11.2, as part of the rear-side metallization MR, completely encloses the through-opening 22. The part of the second edge region 11.2 covered by the insulating layer 24 is now larger than the part covered by the conductive layer 32. In other words, the conductive layer 32 only partially covers the insulating layer 24 on the bottom 10.2.

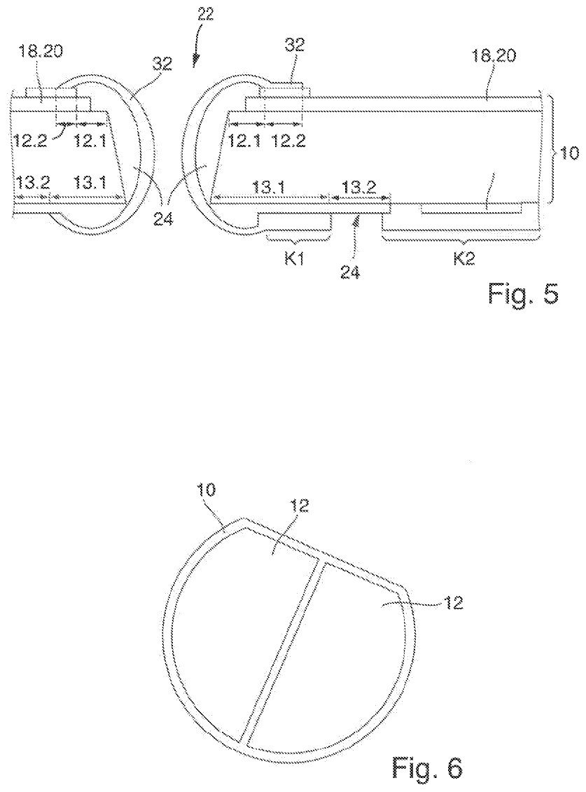

In the illustration in FIG. 5, another cross-sectional view of a metallized through-opening is shown. Only the differences from the illustration in FIG. 1 and the illustration in FIG. 4b are explained below.

On the bottom 10.2, the first section 13.1 of the second edge region 11.2 is widened at least on the right side of the through-opening 22 in order to form a first contact region K1. On the second section 13.2 of the second edge region 11.2, the bottom 10.2 is covered only by the insulating layer 24.

A second contact region K2 is formed on the bottom 10.2 adjacent to the second section 24 as part of the rear-side metallization MR.

The insulating layer 24 is likewise formed in a part of the second contact region K2 on the bottom 10.2 to adjust the height of the second contact region K2. In other words, the rear-side metallization MR is formed integrally on the insulating layer 24 in the second contact region K2.

By this means, the two surfaces of the first contact region K1 and the second contact region K2 can be adjusted so as to solder both contact regions K1 and K2 at the same time.

In the illustration in FIG. 6, a top view of a semiconductor body 10 with two solar cell stacks is shown. In the present case, the semiconductor body 10 has exactly two solar cell stacks 12. It is a matter of course that more than two solar cell stacks 12 can also be formed on the semiconductor body 10 in embodiments that are not shown.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A solar cell contact arrangement comprising:
a semiconductor body with a top and a bottom, wherein the semiconductor body has at least one solar cell stack and includes a support substrate on the bottom, wherein, the at least one solar cell stack has at least two III-V subcells arranged on the support substrate, and at least one through-contact extending from the top to the bottom of the semiconductor body and having a continuous side wall, wherein the through-contact has a first edge region on the top and a second edge region on the bottom, wherein the first edge region has a first section and a second, metallic section, and the second edge region has a first section and a second section;
an insulating layer with a thickness between 5 μm and 200 μm, wherein the insulating layer is formed on the first section in the case of the first edge region, on the side wall, and on the first section and the second section in the case of the second edge region;
an electrically conductive layer formed as a heterogeneous layer with inclusions of gas, the electrically conductive layer having a thickness between 5 μm and 200 μm, and the electrically conductive layer being formed on the first section and at least partially on the second section in the case of the first edge region, at the side wall, and within the first section in the case of the second edge region, and the electrically conductive layer being arranged on the insulating layer.

2. The solar cell contact arrangement according to claim 1, wherein the electrically conductive layer forms a first contact region on the bottom of the support substrate.

3. The solar cell contact arrangement according to claim 1, wherein a second contact region is formed on the bottom of the support substrate, and wherein the support substrate is electrically connected at the bottom via the second contact region.

4. The solar cell contact arrangement according to claim 1, wherein the solar cell stack is electrically connected via the first contact region and via the second contact region.

5. The solar cell contact arrangement according to claim 1, wherein the two contact regions are planar and each have a size of at least 1.0 mm².

6. The solar cell contact arrangement according to claim 2, wherein the two contact regions have at least partly the same height.

7. The solar cell contact arrangement according to claim 1, wherein, after the formation of the conductive layer, the through-opening is partially or completely closed or the through-opening still has a through hole.

8. The solar cell contact arrangement according to claim 1, wherein the first edge region has a smaller diameter than the second edge region.

9. The solar cell contact arrangement according to claim 1, wherein the first edge region and the second edge region are each implemented as an edge region completely surrounding the through-opening and wherein the respective edge region parallel to the semiconductor body has a diameter of at least 10 μm and at most 3.0 mm.

10. The solar cell contact arrangement according to claim 1, wherein the through-opening has a diameter between 25 μm and 1 mm prior to the formation of the insulating layer and the conductive layer.

11. The solar cell contact arrangement according to claim 1, wherein the respective second sections completely enclose the respective first sections.

12. The solar cell contact arrangement according to claim 1, wherein the proportion of the organic constituents in the electrical layer is between 0.1 and 5 volume percent or between 0.2 and 2 volume percent.

13. The solar cell contact arrangement according to claim 1, wherein the thickness of the part of the electrical layer directly at a corner of the first edge region to the through-opening is at least half the thickness of the part of the electrical layer resting on the second edge region.

14. The solar cell contact arrangement according to claim 1, wherein the through-opening is completely filled after the formation of the electrical layer.

15. The solar cell contact arrangement according to claim 1, wherein the insulating layer includes organic components in a range between 0.1 to 5 volume percent.

16. The solar cell contact arrangement according to claim 1, wherein the insulating layer has a thickness between 5 μm and 250 μm and/or the electrically conductive layer has a thickness between 5 μm and 500 μm.

17. The solar cell contact arrangement according to claim 1, wherein the electrically conductive layer has a metal volume fraction of less than 99% and more than 50%, and a maximum electrical conductivity between 30% and 90% of the metallic conductivity of a homogeneously formed metal layer with a material composition that is identical to a first approximation.
